(19) United States
(12) Patent Application Publication
(10) Pub. No.: US 2024/0014794 A1
(43) Pub. Date: Jan. 11, 2024

(54) Impedence Matching Conductive Structure for High Efficiency RF Circuits

(71) Applicant: 3D Glass Solutions, Inc., Albuquerque, NM (US)

(72) Inventors: Jeb H. Flemming, Albuquerque, NM (US); Kyle McWethy, Albuquerque, NM (US)

(21) Appl. No.: 18/307,180

(22) Filed: Apr. 26, 2023

Related U.S. Application Data
(63) Continuation of application No. 16/767,096, filed on May 26, 2020, now Pat. No. 11,677,373.

(51) Int. Cl. H03H 7/38; G06F 30/392; H01L 23/64; H05K 1/02; H05K 1/03; C03C 4/04; H05K 3/10; C03C 15/00

(52) U.S. Cl. CPC H03H 7/38; G06F 30/392; H01L 23/64; H05K 1/025; H05K 1/0306; C03C 4/04; H05K 3/107; C03C 15/00; H05K 3/0017

(57) ABSTRACT

The present invention includes a method of making a RF impedance matching device in a photo definable glass ceramic substrate. A ground plane may be used to adjacent to or below the RF Transmission Line in order to prevent parasitic electronic signals, RF signals, differential voltage build up and floating grounds from disrupting and degrading the performance of isolated electronic devices by the fabrication of electrical isolation and ground plane structures on a photo-definable glass substrate.

### CROSS-REFERENCE TO RELATED APPLICATIONS

This application is a continuation application of U.S. patent application Ser. No. 16/767,096, filed on May 26, 2020, which is the National Stage of International Application No. PCT/US2018/068184, filed on Dec. 31, 2018 claiming the priority to U.S. Provisional Application No. 62/613,735 filed on Jan. 4, 2018, the contents of each of which are incorporated by reference in their entirety.

### STATEMENT OF FEDERALLY FUNDED RESEARCH

None.

### TECHNICAL FIELD OF THE INVENTION

The present invention relates to creating impedance matching between RF devices on the same substrate.

### BACKGROUND OF THE INVENTION

Without limiting the scope of the invention, its background is described in connection with impedance matching.

One such example is taught in U.S. Pat. No. 9,819,991, issued to Rajagopalan, et al., entitled “Adaptive impedance matching interface”. These inventors are said to teach a device that includes a data interface connector, an application processor, and interface circuitry. Interface circuitry is said to be coupled between the application processor and the data interface connector, in which the data interface circuitry determines a change in a signal property of one of the signals, the change being caused by an impedance mismatch between the data interface connector and a media consumption device. The application processor is said to adjust the signal property of a subsequent one of the signals, in response to the signal property setting from the interface circuitry, to obtain an adjusted signal, or can send the adjusted signal to the media consumption device.

Another such example is taught in U.S. Pat. No. 9,755,305, issued to Desclos, et al., and entitled “Active antenna adapted for impedance matching and band switching using a shared component”. Briefly, these inventors are said to teach an active antenna and associated circuit topology that is adapted to provide active impedance matching and band switching of the antenna using a shared tunable component, e.g., using a shared tunable component, such as a tunable capacitor or other tunable component. The antenna is said to provide a low cost and effective active antenna solution, e.g., one or more passive components can be further utilized to design band switching of the antenna from a first frequency to a second desired frequency.

However, despite these advances, a need remains for impedance matching between RF devices on the same substrate.

### SUMMARY OF THE INVENTION

In one embodiment, the present invention includes a method of making an RF impedance matching device comprising: masking a design layout comprising one or more structures to form one or more angled electrical conduction channels on a photosensitive glass substrate; exposing at least one portion of the photosensitive glass substrate to an activating energy source; heating the photosensitive glass substrate for at least ten minutes above its glass transition temperature; cooling the photosensitive glass substrate to transform at least part of the exposed glass to a crystalline material to form a glass-crystalline substrate; etching the glass-crystalline substrate with an etchant solution to form the angled electrical conduction channels of the device; coating the one or more angled electrical conduction channels with one or more metals; and coating all or part of the electrical isolation structure with a metallic media, wherein the metal is connected to a circuitry. In one aspect, the RF impedance matching device has mechanical support under less than 50% of the length or width of the RF impedance matching device. In another aspect, the height of the mechanical support is greater than 10 μm reducing the RF loses. In another aspect, the lateral distance between RF impedance matching device and the substrate is greater than 10 μm reducing the RF loses. In another aspect, the step of etching forms an air gap between the substrate and the RF impedance matching device, wherein the RF impedance matching device is connected to other RF electronic elements. In another aspect, the glass-crystalline substrate adjacent to the trenches may also be converted to a ceramic phase. In another aspect, a conductive structure other than a ground plane of the RF impedance matching device that can be at least one of a microstrip, a stripline, a coplanar wave guide, a grounded coplanar wave guide, or a coaxial waveguide. In another aspect, the one or more metals are selected from Fe, Cu, Au, Ni, In, Ag, Pt, or Pd. In another aspect, the metal is connected to the circuitry through a surface a buried contact, a blind via, a glass via, a straight line contact, a rectangular contact, a polygonal contact, or a circular contact. In another aspect, the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the photosensitive glass substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the photosensitive glass substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the photosensitive glass substrate is a photosensitive glass ceramic composite substrate comprising at least silica, lithium oxide, aluminum oxide, and cerium oxide. In another aspect, the RF impedance matching device has a loss of less than 50, 40, 30, 25, 20, 15, or 10% of the signal input versus an signal output. In another aspect, the method further comprises forming the RF impedance matching device into a feature of at least one of a Time Delay Network, a Directional Couplers Biased Tee, a Fixed Coupler, a Phase Array Antenna, a Filters and Duplexer, a Balun, a Power Combiners/Dividers, or a Power Amplifiers, at frequencies from MHz to THz.

In another embodiment, the present invention includes a method of making a conductive structure for an RF impedance matching device comprising: masking a design layout comprising one or more conductive structures to form one or more angled electrical conduction channels on the photosensitive glass substrate; exposing at least one portion of the photosensitive glass substrate to an activating energy source; processing the photosensitive glass substrate to a heating phase of at least ten minutes above its glass transition temperature; cooling the photosensitive glass substrate to transform at least part of the exposed glass to a crystalline material to form a glass-crystalline substrate; etching the glass-crystalline substrate with an etchant solution to form the one or more angled electrical conduction channels in the device, wherein the glass-crystalline substrate adjacent to the trenches may also be converted to a ceramic phase, and wherein the RF impedance matching device that has mechanical support by less than 50% of the length or width of the RF impedance matching device by the photosensitive glass substrate; coating the one or more angled electrical conduction channels with one or more metals; and coating all or part of the electrical isolation structure with a metallic media, wherein the metal is connected to a circuitry through a surface or buried contact. In one aspect, the one or more conductive structures that include at least one of: a microstrip, a stripline, a coplanar wave guide, a grounded coplanar wave guide, or a coaxial waveguide. In another aspect, the height of the mechanical support is greater than 10 μm reducing the RF loses. In another aspect, the lateral distance between the transmission line and the substrate is greater than 10 μm reducing the RF loses. In another aspect, the step of etching forms an air gap between the substrate and the RF impedance matching device, wherein the transmission line is connected to other RF electronic elements. In another aspect, the one or more metals are selected from Fe, Cu, Au, Ni, In, Ag, Pt, or Pd. In another aspect, the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-15 weight % Li₂O; and 0.001-0.1 weight % CeO₂. In another aspect, the photosensitive glass substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂. In another aspect, the photosensitive glass substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and optionally has an anisotropic-etch ratio of exposed portion to said unexposed portion is at least one of 10-20:1; 21-29:1; 30-45:1; 20-40:1; 41-45:1; and 30-50:1. In another aspect, the photosensitive glass substrate is a photosensitive glass ceramic composite substrate comprising at least silica, lithium oxide, aluminum oxide, and cerium oxide. In another aspect, the RF impedance matching device has a loss of less than 50, 40, 30, 25, 20, 15, or 10% of the signal input versus an signal output. In another aspect, the method further comprises forming the RF impedance matching device into a feature of at least one of a Time Delay Network, a Directional Couplers Biased Tee, a Fixed Coupler, a Phase Array Antenna, a Filters and Duplexer, a Balun, a Power Combiners/Dividers, or a Power Amplifiers, at frequencies from MHz to THz.

In another embodiment, the present invention includes an RF impedance matching device is mechanically support by less than 50% of the length or width of the RF impedance matching device formed on a photo-definable glass the substrate. In one aspect, the RF impedance matching device comprises one or more angled electrical conduction channels on the photosensitive glass substrate. In another aspect, the RF impedance matching device has mechanical support under less than 50% of the length or width of the RF impedance matching device. In another aspect, the height of the mechanical support is greater than 10 μm reducing the RF loses. In another aspect, the lateral distance between the transmission line and the substrate is greater than 10 μm reducing the RF loses. In another aspect, the air gap transmission is connected to other RF electronic elements. In another aspect, the glass-crystalline substrate adjacent to the trenches may also be converted to a ceramic phase. In another aspect, the one or more metals are selected from Fe, Cu, Au, Ni, In, Ag, Pt, or Pd. In another aspect, the metal is connected to the circuitry through a surface a buried contact, a blind via, a glass via, a straight line contact, a rectangular contact, a polygonal contact, or a circular contact. In another aspect, the RF impedance matching device comprises a feature of at least one of a Time Delay Network, a Directional Couplers Biased Tee, a Fixed Coupler, a Phase Array Antenna, a Filters and Duplexer, a Balun, a Power Combiners/Dividers, or a Power Amplifiers, at frequencies from MHz to THz. In another aspect, the RF impedance matching device comprises one or more conductive structures that include at least one of: a microstrip, a stripline, a coplanar wave guide, a grounded coplanar wave guide, or a coaxial waveguide.

### BRIEF DESCRIPTION OF THE DRAWINGS

For a more complete understanding of the features and advantages of the present invention, reference is now made to the detailed description of the invention along with the accompanying figures and in which:

FIGS. 1A and 1B show two variants of microstrip which includes embedded microstrip and coated microstrip, both of which add some dielectric above the microstrip conductor.

FIG. 2A shows a side view of the start of the method in which a lap and polished photodefinable glass substrate that is used, e.g., a 300 μm thick lap and polished photodefinable glass.

FIG. 2B shows a side view DC Sputter a uniform coating of titanium between 200 Å and A thick on the back of the substrate.

FIG. 2C shows a side view of the electroplate a copper ground plane on the back of the substrate. The copper ground plane should be between 0.5 μm and 10 μm thick on the back of the substrate.

FIG. 2D shows a top view of the device formed using a chrome mask with a triangular or trapezoidal clear region to exposed the photodefinable glass substrate. The substrate is 6″ in diameter. The exposure is with approximately 20 J/cm² of 310 nm light. The length L is 100 μm to 200 μm; Width W2 is 10 μm; Width W1 is 50 inn. Next, heat the exposed photodefinable glass to 450° C. for 60 min.

FIG. 2E-1 shows a top view of the etch the exposed photodefinable glass in 10% HF solution down copper/metal ground plane, and FIG. 2E-2 shows a side view of the same device shown in FIG. 2E-1.

FIG. 2F-1 shows a top view of the fill the etched region with a low loss tangent material that is a different dielectric constant than the APEX Glass, and FIG. 2F-2 shows a side view of the same device shown in FIG. 2F-1.

FIG. 2G shows a top view of the device after applying a photoresist and expose a pattern develop and removed the exposed pattern for the microwave stripline.

FIG. 2H shows a top view after DC Sputter a coating of titanium between 200 Å and 10,000 Å thick on the front of the substrate/photoresist.

FIG. 2I is a top view after removing the photoresist using a solvent to expose a titanium pattern on the photodefinable glass substrate.

FIG. 2J is a top view after electroplating a copper in the patterned titanium. The copper should be between 0.5 μm and 10 μm thick on the back of the substrate.

FIG. 2K is a top view after the impedance matching micro strip line is used to connect a variety of devices depicted here as Device 1 and Device 2.

FIG. 3A shows a cross-sectional view of the transmission lines of the present invention.

FIG. 3B is a graph that shows a comparison of the losses of the low loss micro-transmission line of the present invention, when compared to standard glass.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not limit the invention, except as outlined in the claims.

The present invention relates to creating an impedance matching between RF device on the same substrate. Devices such as Filters, Inductors, Capacitors Resistors, Time Delay Networks, Directional Couplers Biased Tees, Fixed Couplers, Phase Array Antenna, Filters & Diplexers, Baluns, Power Combiners/Dividers and Power Amplifiers have different impedance. These devices are often connected by a conductive structure. The conductive structure can be comprised of a microstrip, stripline, coplanar wave guide, grounded coplanar wave guide, and coaxial waveguide. We convenience and brevity will refer to all of these potential conductive structures as a microstrip line. When an RF signal is transmitted between different devices on a microstrip line the impedance difference can create losses or reflected signals. Creating an impedance matching structure reduces losses, improves signal quality (increasing data rates and transmission distance), reduces losses and improves battery life.

Photosensitive glass structures have been suggested for a number of micromachining and microfabrication processes such as integrated electronic elements in conjunction with other elements systems or subsystems. Semiconductor microfabrication using thin film additive processes on semiconductor, insulating or conductive substrates is expensive with low yield and a high variability in performance. An example of additive micro-transmission can be seen in articles Semiconductor microfabrication processes by Tian et al. rely on expensive capital equipment; photolithography and reactive ion etching or ion beam milling tools that generally cost in excess of one million dollars each and require an ultra-clean, high-production silicon fabrication facility costing millions to billions more. This invention provides creates a cost effective glass ceramic electronic individual device or as an array of devices with a uniform response across a large broadband low loss transmission structure.

Microstrip transmission lines consist of a conductive strip of width “W” and thickness “t” and a wider ground plane, separated by a dielectric layer (a.k.a. the “substrate”) of thickness “H” as shown in the figure below. Microstrip is by far the most popular microwave transmission line, especially for microwave integrated circuits and MMICs. The major advantage of microstrip over stripline is that all active components can be mounted on top of the board. The disadvantages are that when high isolation is required such as in a filter or switch, some external shielding may have to be considered. Given the chance, microstrip circuits can radiate, causing unintended circuit response. A minor issue with microstrip is that it is dispersive, meaning that signals of different frequencies travel at slightly different speeds. Microstrip does not support a TEM mode, because of its filling factor. For coupled lines, the even and odd modes will not have the same phase velocity. This property is what causes the asymmetric frequency of microstrip bandpass filters, for example.

Microstrip. FIGS. 1A and 1B shows two variants of microstrip include embedded microstrip and coated microstrip, both of which add some dielectric above the microstrip conductor.

Effective dielectric constant. Because part of the fields from the microstrip conductor exist in air, the effective dielectric constant “Keff” is somewhat less than the substrate's dielectric constant (also known as the relative permittivity). The effective dielectric constant ε_{eff} of microstrip is calculated by:

$$when ( \frac{W}{H} ) < 1 \\ {ε}_{e} = \frac{{ε}_{r} + 1}{2} + \frac{{ε}_{r} - 1}{2} [ {( 1 + 12 ( \frac{H}{W} ) )}^{- 1 / 2} + 0.04 {( 1 - ( \frac{W}{H} ) )}^{2} ] \\ when ( \frac{W}{H} ) \geq 1 \\ {ε}_{e} = \frac{{ε}_{r} + 1}{2} + \frac{{ε}_{r} - 1}{2} {( 1 + 12 ( \frac{H}{W} ) )}^{- 1 / 2}$$

The effective dielectric constant is a seen to be a function of the ratio of the width to the microstrip line to the height of substrate (W/H), as well as the dielectric constant of the substrate material.

Characteristic impedance. Characteristic impedance Zo of microstrip is also a function of the ratio of the height to the width W/H (and ratio of width to height H/W) of the transmission line, and also has separate solutions depending on the value of W/H. The characteristic impedance Zo of microstrip is calculated by:

$$when ( \frac{W}{H} ) < 1 \\ {Z}_{0} = \frac{60}{\sqrt{{ε}_{eff}}} ln ( 8 \frac{H}{W} + 0.25 \frac{W}{H} ) ( ohms ) \\ when ( \frac{W}{H} ) \geq 1 \\ {Z}_{0} = \frac{120 π}{\sqrt{{ε}_{egff}} \times [ \frac{W}{H} + 1.393 + \frac{2}{3} ln ( \frac{W}{H} + 1.444 ) ]} ( ohms )$$

Impedance matched RF circuit requires optimizing the:
a. Thickness of the substrate H bellow the microstrip line;
b. Dielectric constant of the substrate bellow the microstrip line; and
c. Width of the microstrip line.

The present invention includes a method to fabricate a substrate with RF impedance matching device structures RF devices on a photodefinable glass ceramic substrate. In general the impedance matching device is formed by etching a triangular via through the photodefinable glass ceramic, then filling the with a non conductive media with a different dielectric constant that is different from the photodefinable glass ceramic substrate. The metal line that connects the RF devices transverses the length of the filled triangular shaped region from the narrow to wide end.

To address these needs, the present inventors developed a glass ceramic (APEX® Glass ceramic) as a novel packaging and substrate material for semiconductors, RF electronics, microwave electronics, and optical imaging. APEX® Glass ceramic is processed using first generation semiconductor equipment in a simple three step process and the final material can be fashioned into either glass, ceramic, or contain regions of both glass and ceramic. Photo-etchable glasses have several advantages for the fabrication of a wide variety of microsystems components.

Microstructures have been produced relatively inexpensively with these glasses using conventional semiconductor processing equipment. In general, glasses have high temperature stability, good mechanical a n d electrically properties, and have better chemical resistance than plastics and many metals. Photoetchable glass is comprised of lithium-aluminum-silicate glass containing traces of silver ions. When exposed to UV-light within the absorption band of cerium oxide, the cerium oxide acts as sensitizers, absorbing a photon and losing an electron that reduces neighboring silver oxide to form silver atoms, e.g.,

Ce³⁺+Ag⁺=Ce⁴⁺+Ag⁰

The silver atoms coalesce into silver nanoclusters during the baking process and induce nucleation sites for crystallization of the surrounding glass. If exposed to UV light through a mask, only the exposed regions of the glass will crystallize during subsequent heat treatment.

This heat treatment must be performed at a temperature near the glass transformation temperature (e.g., greater than 465° C. in air). The crystalline phase is more soluble in etchants, such as hydrofluoric acid (HF), than the unexposed vitreous, amorphous regions. The crystalline regions etched greater than 20 times faster than the amorphous regions in 10% HF, enabling microstructures with wall slopes ratios of about 20:1 when the exposed regions are removed. See T. R. Dietrich et al., “Fabrication technologies for microsystems utilizing photoetchable glass,” Microelectronic Engineering 30, 497 (1996), which is incorporated herein by reference.

In general photoetchable glass and is composed of silicon oxide (SiO₂) of 75-85% by weight, lithium oxide (Li₂O) of 7-11% by weight, aluminum oxide (Al₂O₃) of 3-6% by weight, sodium oxide (Na₂O) of 1-2% by weight, 0.2-0.5% by weight antimonium trioxide (Sb₂O₃) or arsenic oxide (As₂O₃), silver oxide (Ag₂O) of 0.05-0.15% by weight, and cerium oxide (CeO₂) of 0.01-0.04% by weight. As used herein the terms “APEX® Glass ceramic”, “APEX glass” or simply “APEX” is used to denote one embodiment of the glass ceramic composition of the present invention.

APEX composition provides three main mechanisms for its enhanced performance: (1) The higher amount of silver leads to the formation of smaller ceramic crystals which are etched faster at the grain boundaries, (2) the decrease in silica content (the main constituent etched by the HF acid) decreases the undesired etching of unexposed material, and (3) the higher total weight percent of the alkali metals and boron oxide produces a much more homogeneous glass during manufacturing.

The present invention includes a method for fabricating a low loss RF impedance matching structure in APEX Glass structure for use in forming angled structures, mirrors and glass ceramic materials used in electromagnetic transmission and filtering applications. The present invention includes an angled structure created in the multiple planes of a glass-ceramic substrate, such process employing the (a) exposure to excitation energy such that the exposure occurs at various angles by either altering the orientation of the substrate or of the energy source, (b) a bake step and (c) an etch step. Angle sizes can be either acute or obtuse. The curved and digital structures are difficult, if not infeasible to create in most glass, ceramic or silicon substrates. The present invention has created the capability to create such structures in both the vertical as well as horizontal plane for glass-ceramic substrates.

Ceramicization of the glass is accomplished by exposing a region of the APEX Glass substrate to approximately 20 J/cm² of 310 nm light. In one embodiment, the present invention provides a quartz/chrome mask containing a variety of concentric circles with different diameters.

The present invention includes a method for fabricating a RF impedance matching microstrip line used to connect different electronic devices fabricated in or attached to the photosensitive glass. The RF impedance matching microstrip line can connect devices including but not limited to: Filters, Inductors, Capacitors Resistors, Time Delay Networks, Directional Couplers Biased Tees, Fixed Couplers, Phase Array Antenna, Filters & Diplexers, Baluns, Power Combiners/Dividers and Power Amplifiers. The photosensitive glass substrate can having a wide number of compositional variations including but not limited to: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃; and Al₂O₃ not exceeding 13 weight %; 8-weight % Li₂O; and 0.001-0.1 weight % CeO₂. This and other varied compositions are generally referred to as the APEX glass.

The exposed portion may be transformed into a crystalline material by heating the glass substrate to a temperature near the glass transformation temperature. When etching the glass substrate in an etchant such as hydrofluoric acid, the anisotropic-etch ratio of the exposed portion to the unexposed portion is at least 30:1 when the glass is exposed to a broad spectrum mid-ultraviolet (about 308-312 nm) flood lamp to provide a shaped glass structure that have an aspect ratio of at least 30:1, and to provide a lens shaped glass structure. The mask for the exposure can be of a halftone mask that provides a continuous grey scale to the exposure to form a curved structure for the micro lens. A digital mask used with the flood exposure can be used to produce a diffractive optical element or Fresnel lens. The exposed glass is then baked typically in a two-step process. Temperature range heated between of 420° C.-520° C. for between 10 minutes to 2 hours, for the coalescing of silver ions into silver nanoparticles and temperature range heated between 520° C.-620° C. for between 10 minutes and 2 hours allowing the lithium oxide to form around the silver nanoparticles. The glass plate is then etched. The glass substrate is etched in an etchant, of HF solution, typically 5% to 10% by volume, wherein the etch ratio of exposed portion to that of the unexposed portion is at least 30:1. Create the impedance matching strip line structure requires this general processing approach.

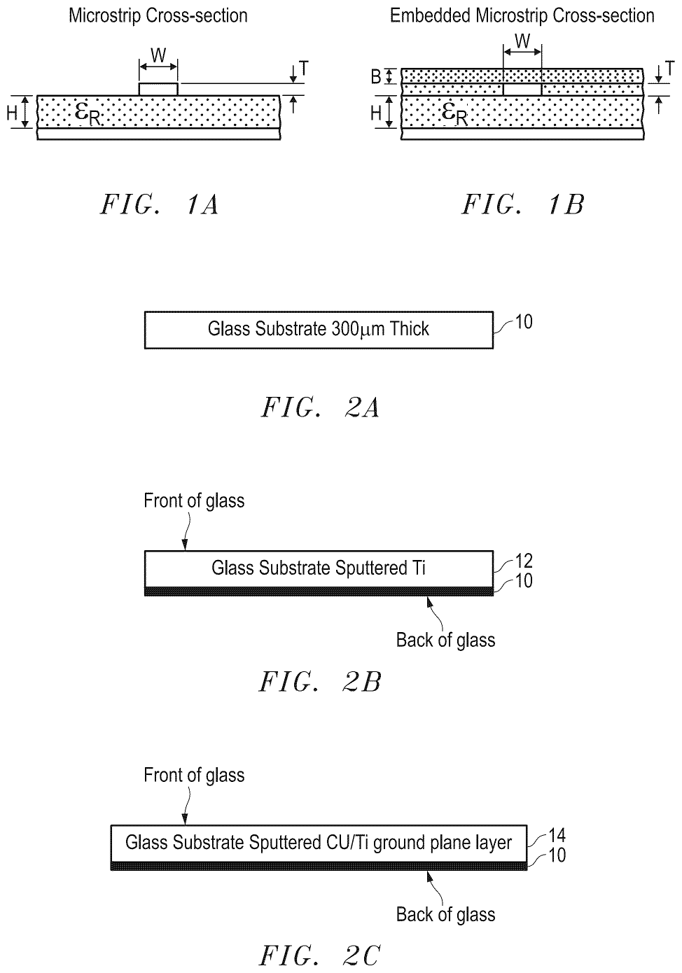

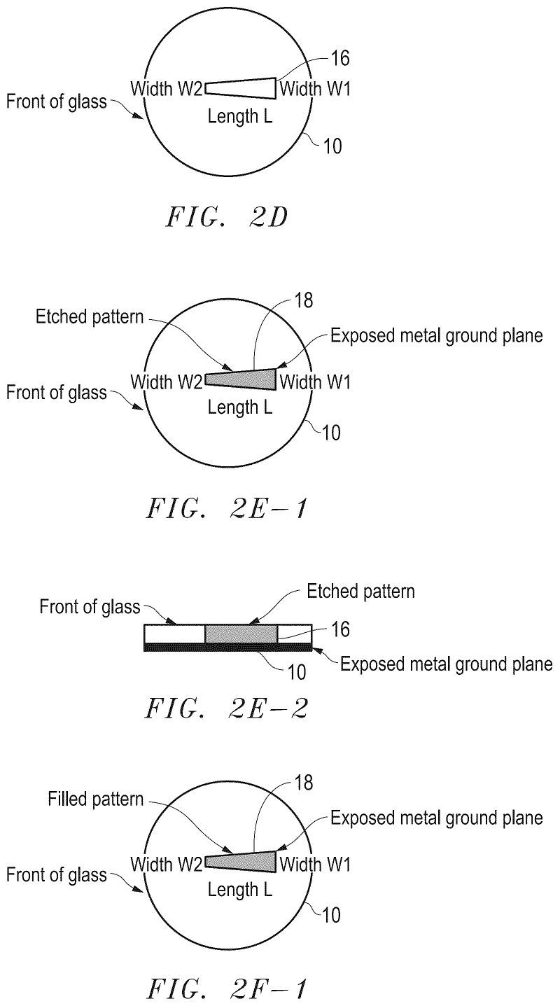

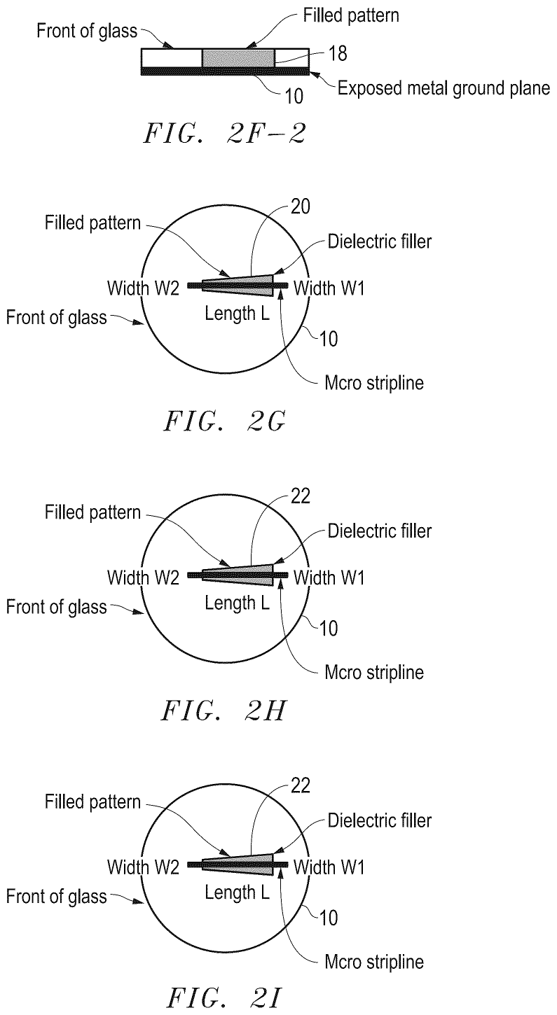

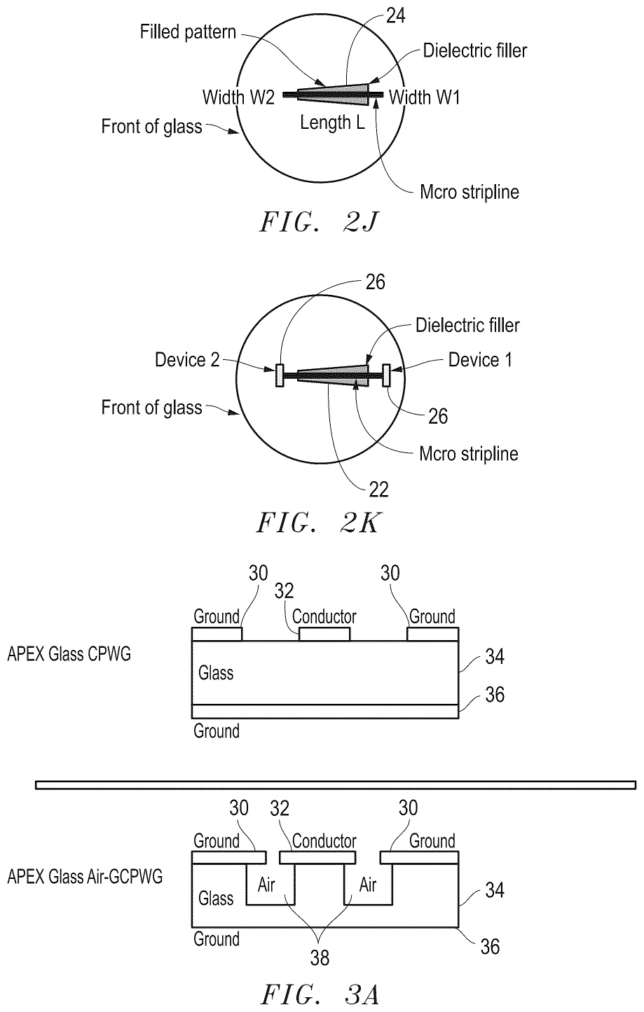

FIG. 2A shows a side view of the start of the method in which a lap and polished photodefinable glass substrate 10 that is used, e.g., a 300 μm thick lap and polished photodefinable glass.

FIG. 2B shows a side view DC Sputter a uniform coating of titanium 12 between 200 Å and 10,000 Å thick on the back of the photodefinable glass substrate 10.

FIG. 2C shows a side view of the electroplate a copper ground plane on the back of the substrate. The copper ground plane 14 should be between 0.5 μm and 10 μm thick on the back of the photodefinable glass substrate 10.

FIG. 2D shows a top view of the device formed using a chrome mask 16 with a triangular or trapezoidal clear region to exposed the photodefinable glass substrate 10. The substrate is 6″ in diameter. The exposure is with approximately 20 J/cm² of 310 nm light. The length L is 100 μm to 200 μm; Width W2 is 10 inn; Width W1 is 50 μm. Next, heat the exposed photodefinable glass to 450° C. for 60 min.

FIG. 2E-1 shows a top view of the etch the exposed photodefinable glass substrate 10 in 10% HF solution down copper/metal ground plane 18, and FIG. 2E-2 shows a side view of the same device shown in FIG. 2E-1.

FIG. 2G-1 shows a top view of the fill the etched region with a low loss tangent material that is a different dielectric constant than the APEX Glass, and FIG. 2G-2 shows a side view of the same device shown in FIG. 2G-1. For a low dielectric constant requirement the patterned structure can be filled with a spin on glass from Allied Signal (methyl siloxane spin-on-glass). For high dielectric requirements the patterned structure can be filled with, e.g., a BaTiO₃ paste from Advance Materials. Next, the feature is heat treated on the photodefinable glass substrate 10 to 600° C. for 1 hour.

FIG. 2H shows a top view of the device after applying a photoresist 20 and expose a pattern develop and removed the exposed pattern for the microwave stripline.

FIG. 2I shows a top view after DC Sputter a coating of titanium 22 between 200 Å and 10,000 Å thick on the front of the substrate/photoresist 10.

FIG. 2J is a top view after removing the photoresist using a solvent to expose a titanium pattern 24 on the photodefinable glass substrate.

FIG. 2K is a top view after electroplating a copper in the patterned titanium. The copper should be between 0.5 μm and 10 μm thick on the back of the substrate. If the application requires an air gap then the wafer is exposed to a 0.5% HF etch removing the spin on glass.

FIG. 2L is a top view after the impedance matching micro strip line is used to connect a variety of devices depicted here as Device 1 and Device 2 at contacts 26.

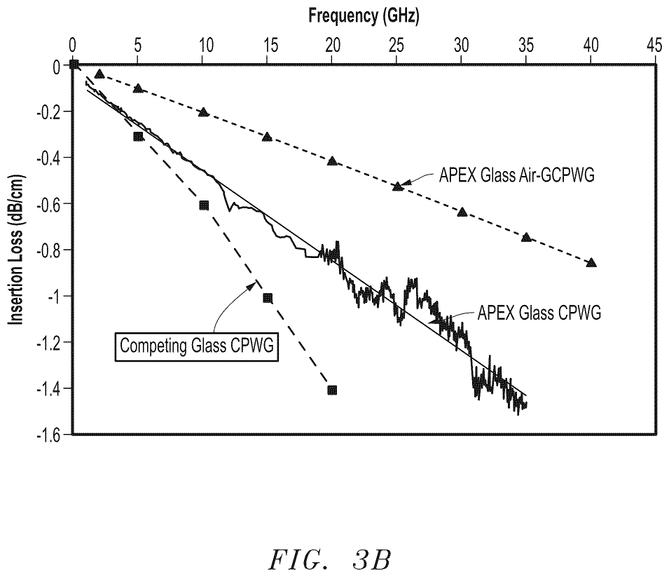

FIG. 3A top shows a cross-sectional view of the transmission line of the present invention that includes: grounds 30, conductor 32, photodefinable glass substrate 34 and ground 36. FIG. 3B (bottom) shows another example of the transmission line of the present invention that includes an air-gap, and the figures shows the grounds 30, the conductor 32, the photodefinable glass substrate 34, the ground 36, and air gaps (dielectric) 38.

FIG. 3B is a graph that shows a comparison of the losses of the low loss micro-transmission line of the present invention, when compared to standard glass.

Thus, the present invention has built and simulated a micro strip line using air as the dielectric material, the width of the dielectric trapezoid W1 is at 100 um and is reduced to W2 to 50 um. Again, the loss tangent for APEX glass is defined to be 0.02 at 60 GHz. All metals are 10 μm thick Cu with a 500 Å Ti adhesion layer, however, the skilled artisan will recognize that the requirements of a device (overall power, current, resistance, etc.) will dictate the materials used, the thickness and length of the device, and the tolerance to signal-to-noise ratio, etc., to accommodate the specific requirements of the device, as will be known to the skilled artisan in light of the specification and the formulas hereinabove. The photodefinable glass substrate used in this example has a 6″ diameter and 300 μm thickness, however, both of those can easily be varied as will be known to the skilled artisan. The insertion loss for this 1 cm long line is 0.495 dB at 60 GHz. This level of insertion loss is unprecedented in RF devices particularly compared to PCB based RF products.

The present inventors used a photo-definable glass ceramic (APEX®) Glass Ceramic or other photo definable glass as a novel substrate material for semiconductors, RF electronics, microwave electronics, electronic components and/or optical elements. In general, a photo definable glass is processed using first generation semiconductor equipment in a simple three step process and the final material can be fashioned into either glass, ceramic, or contain regions of both glass and ceramic. Low loss micro-transmission transmission lines are the base line structure that enable, e.g.: Time Delay Networks, Directional Couplers Biased Tees, Fixed Couplers, Phase Array Antenna, Filters and Diplexers, Baluns, Power Combiners/Dividers and Power Amplifiers, at frequencies from MHz to THz devices thereby dramatically improving the efficiency and performance. The low loss micro-transmission transmission lines are the base line structure that enable, e.g.: Time Delay Networks, Directional Couplers Biased Tees, Fixed Couplers, Phase Array Antenna, Filters and Diplexers, Baluns, Power Combiners/Dividers and Power Amplifiers, at frequencies from MHz to THz devices while reducing the size. Alternatively, the low loss micro-transmission transmission lines at frequencies from MHz to THz devices can thereby dramatically improving the efficiency and performance and reducing the size.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting” essentially of or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), property(ies), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

To aid the Patent Office, and any readers of any patent issued on this application in interpreting the claims appended hereto, applicants wish to note that they do not intend any of the appended claims to invoke paragraph 6 of 35 U.S.C. § 112, U.S.C. § 112 paragraph (f), or equivalent, as it exists on the date of filing hereof unless the words “means for” or “step for” are explicitly used in the particular claim.

For each of the claims, each dependent claim can depend both from the independent claim and from each of the prior dependent claims for each and every claim so long as the prior claim provides a proper antecedent basis for a claim term or element.

What is claimed is:

1. A method of making an RF impedance matching device comprising:
masking a design layout comprising one or more structures to form one or more triangular or trapezoidal vias on a photosensitive glass substrate;
exposing at least one portion of the photosensitive glass substrate to an activating energy source;
heating the photosensitive glass substrate for at least ten minutes above its glass transition temperature;
cooling the photosensitive glass substrate to transform at least part of the exposed at least one portion of the photosensitive glass substrate to a crystalline material to form a glass-crystalline substrate;
etching the glass-crystalline substrate with an etchant solution to form the one or more triangular or trapezoidal vias;
filling the one or more triangular or trapezoidal vias with a non-conductive medium having a dielectric constant that is different from a dielectric constant of the photosensitive glass substrate; and
forming one or more conductive structures to traverse the one or mor triangular or trapezoidal vias.

2. The method of claim 1, wherein the RF impedance matching device has mechanical support under less than 50% of a length or width of the RF impedance matching device.

3. The method of claim 1, wherein a height of a mechanical support is greater than 10 μm reducing RF loses.

4. The method of claim 1, wherein the lateral distance between RF impedance matching device and the substrate is greater than 10 μm reducing RF loses.

5. The method of claim 1, wherein the step of etching forms an air gap between the photosensitive glass substrate and the RF impedance matching device, wherein the RF impedance matching device is connected to other RF electronic elements.

6. The method of claim 1, wherein a conductive structure other than a ground plane of the RF impedance matching device that can be at least one of a microstrip, a stripline, a coplanar wave guide, a grounded coplanar wave guide, or a coaxial waveguide.

7. The method of claim 1, wherein the one or more conductive structures comprise one or more metals selected from Fe, Cu, Au, Ni, In, Ag, Pt, or Pd.

8. The method of claim 1, wherein the one or more conductive structures are configured to be connected to circuitry through a surface contact, a buried contact, a blind via, a glass via, a straight line contact, a rectangular contact, a polygonal contact, or a circular contact.

9. The method of claim 1, wherein the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃ and Al₂O₃ not exceeding 13 weight %; 8-15 weight % Li₂O; and 0.001-0.1 weight % CeO₂.

10. The method of claim 1, wherein the photosensitive glass substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂.

11. The method of claim 1, wherein the photosensitive glass substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and has an anisotropic-etch ratio of an exposed portion to an unexposed portion is at least one of 10-21-29:1; 30-45:1; 20-40:1; 41-45:1; and 30-50:1.

12. The method of claim 1, wherein the photosensitive glass substrate is a photosensitive glass ceramic composite substrate comprising at least silica, lithium oxide, aluminum oxide, and cerium oxide.

13. The method of claim 1, wherein the RF impedance matching device has a loss of less than 50, 40, 30, 25, 20, 15, or 10% of a signal input versus a signal output.

14. The method of claim 1, further comprising forming the RF impedance matching device into a feature of at least one of a Time Delay Network, a Directional Couplers Biased Tee, a Fixed Coupler, a Phase Array Antenna, a Filters and Duplexer, a Balun, a Power Combiners/Dividers, or a Power Amplifiers, at frequencies from MHz to THz.

15. A method of making a conductive structure for an RF impedance matching device comprising:
masking a design layout comprising one or more conductive structures to form one or more triangular or trapezoidal vias on a photosensitive glass substrate;
exposing at least one portion of the photosensitive glass substrate to an activating energy source;
processing the photosensitive glass substrate to a heating phase of at least ten minutes above its glass transition temperature;
cooling the photosensitive glass substrate to transform at least part of the exposed at least one portion of the photosensitive glass substrate to a crystalline material to form a glass-crystalline substrate;
etching the glass-crystalline substrate with an etchant solution to form the one or more triangular or trapezoidal vias, wherein the RF impedance matching device has mechanical support by less than 50% of a length or width of the RF impedance matching device by the photosensitive glass substrate;
filling the one or more triangular or trapezoidal vias with a non-conductive medium having a dielectric constant that is different from a dielectric constant of the photosensitive glass substrate; and
forming one or more conductive structures to traverse the one or mor triangular or trapezoidal vias.

16. The method of claim 15, wherein the one or more conductive structures include at least one of: a microstrip, a stripline, a coplanar wave guide, a grounded coplanar wave guide, or a coaxial waveguide.

17. The method of claim 15, wherein a height of the mechanical support is greater than 10 μm reducing RF loses.

18. The method of claim 15, wherein the lateral distance between the one or more conductive structures and the substrate is greater than 10 μm reducing RF loses.

19. The method of claim 15, wherein the step of etching forms an air gap between the substrate and the RF impedance matching device, wherein the RF impedance matching device is connected to other RF electronic elements.

20. The method of claim 15, wherein the one or more conductive structures comprise one or more metals selected from Fe, Cu, Au, Ni, In, Ag, Pt, or Pd.

21. The method of claim 15, wherein the photosensitive glass substrate is a glass substrate comprising a composition of: 60-76 weight % silica; at least 3 weight % K₂O with 6 weight %-16 weight % of a combination of K₂O and Na₂O; 0.003-1 weight % of at least one oxide selected from the group consisting of Ag₂O and Au₂O; 0.003-2 weight % Cu₂O; 0.75 weight %-7 weight % B₂O₃, and 6-7 weight % Al₂O₃; with the combination of B₂O₃ and Al₂O₃ not exceeding 13 weight %; 8-15 weight % Li₂O; and 0.001-0.1 weight % CeO₂.

22. The method of claim 15, wherein the photosensitive glass substrate is a glass substrate comprising a composition of: 35-76 weight % silica, 3-16 weight % K₂O, 0.003-1 weight % Ag₂O, 0.75-13 weight % B₂O₃, 8-15 weight % Li₂O, and 0.001-0.1 weight % CeO₂.

23. The method of claim 15, wherein the photosensitive glass substrate is at least one of: a photo-definable glass substrate comprises at least 0.3 weight % Sb₂O₃ or As₂O₃; a photo-definable glass substrate comprises 0.003-1 weight % Au₂O; a photo-definable glass substrate comprises 1-18 weight % of an oxide selected from the group consisting of CaO, ZnO, PbO, MgO and BaO; and has an anisotropic-etch ratio of an exposed portion to an unexposed portion is at least one of 10-20:1; 21-29:1; 30-45:1; 20-40:1; 41-45:1; and 30-50:1.

24. The method of claim 15, wherein the photosensitive glass substrate is a photosensitive glass ceramic composite substrate comprising at least silica, lithium oxide, aluminum oxide, and cerium oxide.

25. The method of claim 15, wherein the RF impedance matching device has a loss of less than 50, 40, 30, 25, 20, 15, or 10% of a signal input versus a signal output.

26. The method of claim 15, further comprising forming the RF impedance matching device into a feature of at least one of a Time Delay Network, a Directional Couplers Biased Tee, a Fixed Coupler, a Phase Array Antenna, a Filter and Duplexer, a Balun, a Power Combiner/Divider, or a Power Amplifier, at frequencies from MHz to THz.

27. An RF impedance matching device mechanically supported by less than 50% of a length or width of the RF impedance matching device formed on a photosensitive glass substrate, comprising one or more triangular or trapezoidal vias on the photosensitive glass substrate.

28. The device of claim 27, wherein the RF impedance matching device has mechanical support under less than 50% of a length or width of the RF impedance matching device.

29. The device of claim 27, wherein a height of the mechanical support is greater than 10 μm reducing RF loses.

30. The device of claim 27, wherein the lateral distance between the one pr more conductive structures and the photosensitive glass substrate is greater than 10 μm reducing RF loses.

31. The device of claim 27, wherein the one or more conductive structures comprise one or more metals selected from Fe, Cu, Au, Ni, In, Ag, Pt, or Pd.

32. The device of claim 27, wherein the device is connected to circuitry through a surface contact, a buried contact, a blind via, a glass via, a straight line contact, a rectangular contact, a polygonal contact, or a circular contact.

33. The device of claim 27, wherein the RF impedance matching device comprises a feature of at least one of a Time Delay Network, a Directional Couplers Biased Tee, a Fixed Coupler, a Phase Array Antenna, a Filter and Duplexer, a Balun, a Power Combiner/Divider, or a Power Amplifiers, at frequencies from MHz to THz.

34. The device of claim 27, wherein the RF impedance matching device comprises one or more conductive structures that include at least one of: a microstrip, a stripline, a coplanar wave guide, a grounded coplanar wave guide, or a coaxial waveguide.
